(19) United States
(12) Patent Application Publication
(10) Pub. No.: US 2010/0184286 A1
(43) Pub. Date: Jul. 22, 2010

(54) METHOD FOR MANUFACTURING SEMICONDUCTOR DEVICE

(75) Inventor: Takashi KANSAKU, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/641,653

(22) Filed: Dec. 18, 2009

(30) Foreign Application Priority Data
Jan. 19, 2009 (JP) 2009-008949

(51) Int. Cl. H01L 21/768

(52) U.S. Cl. 438/625; 257/E21.585

(57) ABSTRACT

A method for manufacturing a semiconductor device comprises forming a metal wiring on a semiconductor substrate, forming an insulating film over the semiconductor substrate with the metal wiring, forming a through hole in the insulating film, performing sputter-etching to enlarge an cross section of the through hole, and forming a stacked film. In forming the stacked film, there are formed a first titanium film, a titanium nitride film, and a second titanium film in this order over the insulating film including an inner surface of the through hole at a temperature within a range from 20 to 40° C., and a first Al layer, a second Al layer, and a third Al layer in this order over the second titanium film.

This application is based upon and claims the benefit of priority from Japanese Patent Application No. 2009-008949, filed on Jan. 19, 2009, the disclosure of which is incorporated herein in its entirety by reference.

### BACKGROUND OF THE INVENTION

1. Field of the Invention

The present invention relates to a method for manufacturing a semiconductor device.

2. Description of the Related Art

A semiconductor device primarily includes functional elements, such as transistors, diodes, and capacitors, formed on a semiconductor substrate and wirings for connecting the functional elements to form a circuit. In recent years, a multilayer wiring structure is used as the wirings to increase the integration level or enhance the functionality of a semiconductor device.

A multilayer wiring structure requires via plugs that connect lower-layer wirings to upper-layer wirings via through holes. When the upper-layer wirings are made of Al, however, it has been difficult to completely fill the through holes with Al only by depositing Al in a sputtering process as the integration level increases and the diameter of each of the through holes decreases accordingly. A method for depositing Al in a high-temperature reflow process and a method for heat-treating deposited Al to allow the Al to reflow have been used.

Japanese Patent Laid-Open No. 2001-015515 discloses a method for connecting a diffusion layer formed in a semiconductor substrate to upper-layer Al wirings via contact holes formed in an insulating film. More specifically, Japanese Patent Laid-Open No. 2001-015515 describes a method for forming a titanium (Ti) film formed as a barrier layer under the Al portion at a temperature within a range from 100 to 250° C. to improve the crystallizability of the Al portion formed on the Ti film, whereby improving the reliability of the wirings.

FIG. 11 is a copy of FIG. 5 that accompanies Japanese Patent Laid-Open No. 2001-015515. The technique described in Japanese Patent Laid-Open No. 2001-015515 will be described below.

First, a contact hole is formed in insulating film 11 formed on semiconductor substrate 10. The semiconductor substrate is then heated to a temperature within a range from 100 to 250° C., and titanium film 13 is formed over the surface to a thickness of approximately 20 nm. Thereafter, titanium nitride film 14, which will work as barrier metal, is formed over the surface. The resultant structure then undergoes a heat treatment in a nitrogen atmosphere at 600° C. to reduce contact resistance.

Thereafter, titanium film 15 is formed over the surface so that junction of the structure with an Al film improves. Al film 16 is then formed over the surface by a low-temperature sputtering process, and Al film 17 is further formed over the surface by a high-temperature sputtering process, whereby the contact hole is filled with Al and reflowed Al wiring layer 18 is formed at the same time.

Japanese Patent Laid-Open No. 2001-015515 describes that the method described above can improve the crystallizability of titanium film 13 and hence the crystallizability of Al wiring layer 18, whereby a reliable wiring layer is advantageously provided.

### SUMMARY OF THE INVENTION

In one embodiment, there is provided a method for manufacturing a semiconductor device, the method comprising:

forming a metal wiring on a semiconductor substrate;

forming an insulating film over the semiconductor substrate with the metal wiring;

forming a through hole passing through the insulating film in a thickness direction thereof so that an upper surface of the metal wiring is exposed;

performing sputter-etching to enlarge a cross-sectional area of an opening of the through hole;

forming a first titanium film, a titanium nitride film, and a second titanium film in this order over the insulating film including an inner surface of the through hole at a temperature within a range from 20 to 40° C.; forming a first Al layer on the second titanium film;

forming a second Al layer on the first Al layer; and

forming a third Al layer on the second Al layer.

In another embodiment, there is provided a method for manufacturing a semiconductor device, the method comprising:

forming a metal wiring on a semiconductor substrate;

forming an insulating film over the semiconductor substrate with the metal wiring;

forming a through hole passing through the insulating film in a thickness direction thereof so that an upper surface of the metal wiring is exposed;

performing sputter-etching to enlarge a cross-sectional area of an opening of the through hole;

forming a first conductive film, a second conductive film, and a third conductive film in this order over the insulating film including an inner surface of the through hole at a temperature within a range from 20 to 40° C.;

forming a fourth conductive film on the third conductive film;

forming a fifth conductive film on the fourth conductive film; and

forming a sixth conductive film on the fifth conductive film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a flowchart describing an exemplary method for manufacturing a semiconductor device according to the present invention;

FIG. 2 illustrates a step in the exemplary method for manufacturing a semiconductor device according to the present invention;

FIG. 3 illustrates a step in the exemplary method for manufacturing a semiconductor device according to the present invention;

FIG. 4 illustrates a step in the exemplary method for manufacturing a semiconductor device according to the present invention;

FIG. 5 illustrates a step in the exemplary method for manufacturing a semiconductor device according to the present invention;

FIG. 6 illustrates a step in the exemplary method for manufacturing a semiconductor device according to the present invention;

FIG. 7 illustrates a step in the exemplary method for manufacturing a semiconductor device according to the present invention;

FIG. 8 illustrates a step in the exemplary method for manufacturing a semiconductor device according to the present invention;

FIG. 9 illustrates a step in the exemplary method for manufacturing a semiconductor device according to the present invention;

FIG. 10 shows how much target material is buried in a hole in exemplary embodiments and Comparative Examples;

FIG. 11 describes a related semiconductor device;

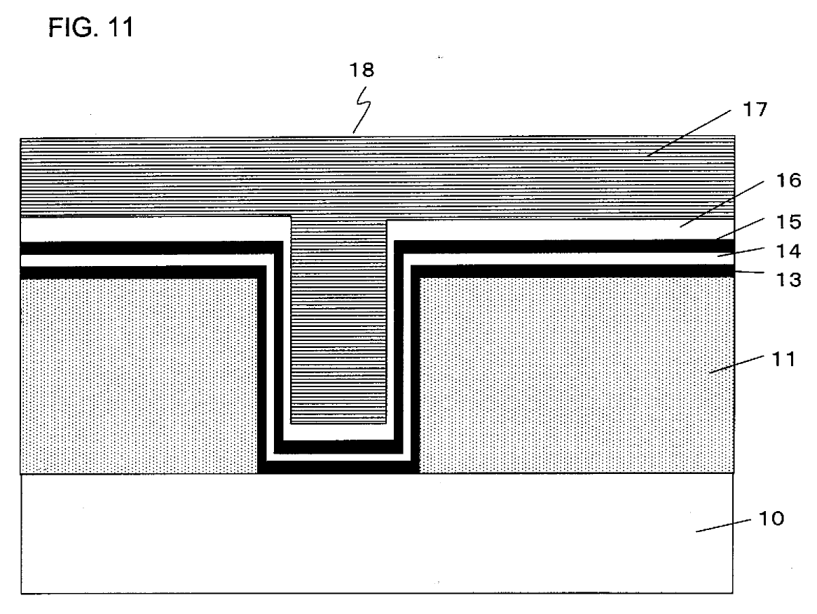

FIG. 12 describes a related semiconductor device; and

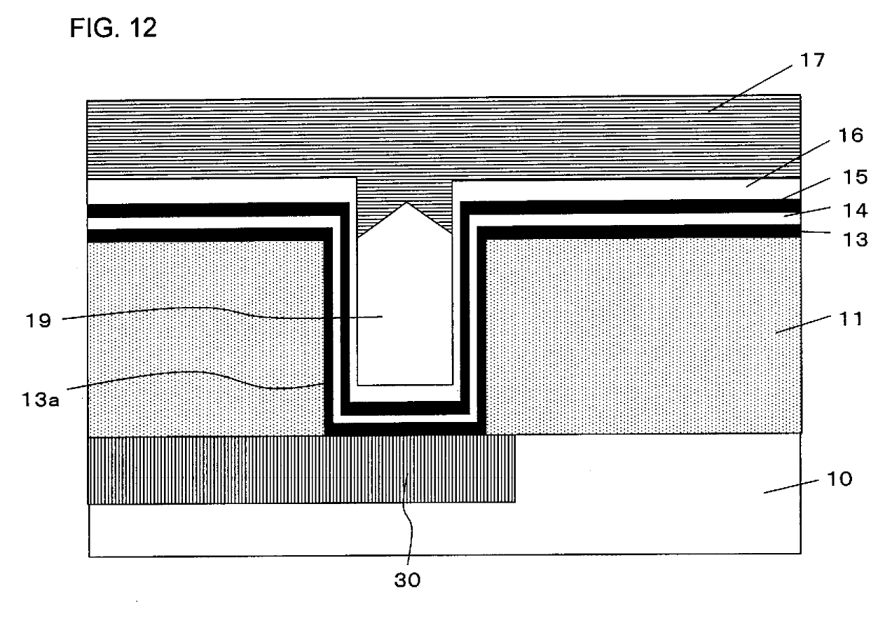

FIG. 13 describes a related semiconductor device.

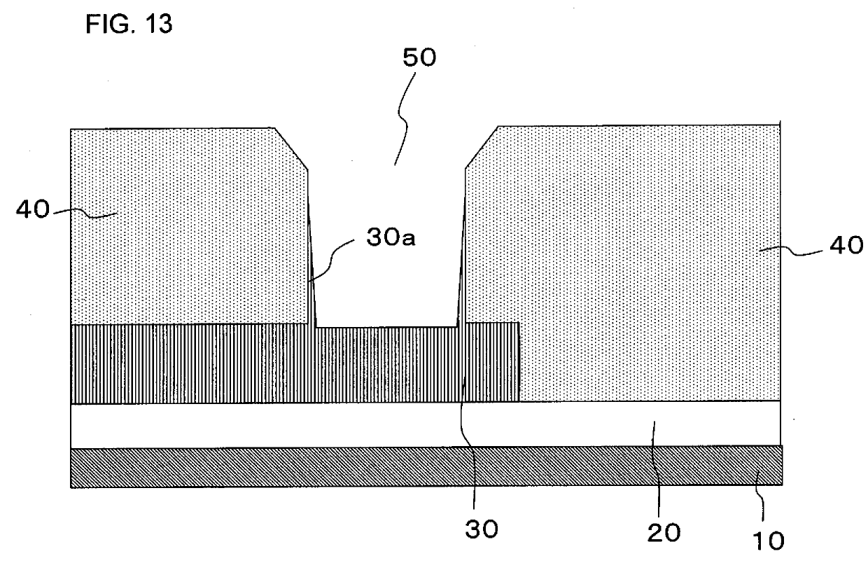

In the drawings, numerals have the following meanings. 1, 10: semiconductor substrate, 2, 4, 11, 20, 40: interlayer insulating film, 3, 30: metal wiring, 3a: Al oxide, 5, 50 through hole, 5a inclined portion, 6: first titanium film, 7, 14, 31: titanium nitride film, 8: second titanium film, 9a: first Al layer, 9b: second Al layer, 9c: third Al layer, 13, 15: titanium film, 13a: titanium film, 16, 17: Al film, 18: Al wiring layer, 19: void, 30a: metal oxide film, 31a: titanium oxide.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

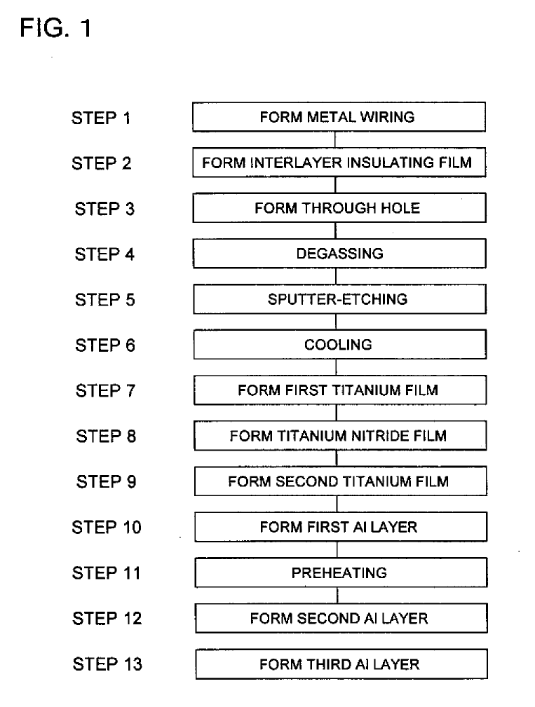

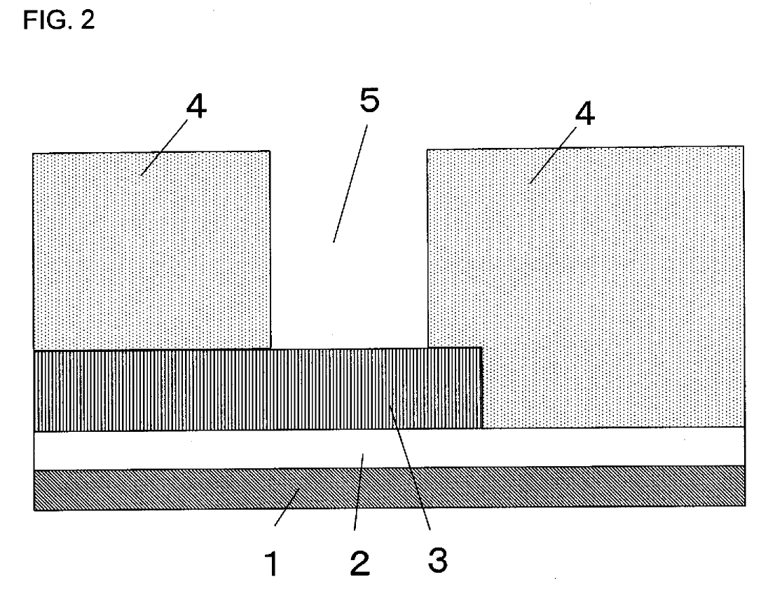

A first exemplary embodiment will be described below with reference to FIGS. 1 to 8. FIG. 1 shows an overall procedure of a method for manufacturing a semiconductor device of the first exemplary embodiment, and the steps that form the method are shown in the execution order. FIGS. 2 to 8 are cross-sectional views, each of which describes the state of the semiconductor device after the corresponding step shown in FIG. 1 is executed. In the following description, each of the steps shown in FIG. 1 will be described by using the reference numerals of members drawn in the cross-sectional views of FIGS. 2 to 8.

First, in step 1, a metal wiring is formed. As shown in FIG. 2, metal wiring 3 made of Al is formed on semiconductor substrate 1 with interlayer insulating film 2 therebetween. The Al can be pure Al or Cu-containing Al.

The wiring is formed by performing lithography and dry etching on Al deposited over the semiconductor substrate by sputtering. After Al wiring 3 is formed, the material (not illustrated in FIG. 2) of a mask used in the dry etching is removed. When metal wiring 3 is made of Cu, a known Damascene process can be used to form the wiring.

The semiconductor substrate can be made of silicon or, for example, any suitable compound semiconductor. On the semiconductor substrate, for example, are formed transistors, diodes, and other active elements and resistors, a plurality of wiring layers, and other passive elements. The series of processes in step 1 are carried out by using a metal sputtering apparatus, a lithography apparatus, and a dry etching apparatus, each of which is a separate apparatus.

In step 2, an interlayer insulating film is formed. As shown in FIG. 2, interlayer insulating film 4 is formed over the semiconductor substrate on which Al wiring 3 is formed. The thickness of interlayer insulating film 4 ranges from 700 to 1000 nm. An example of interlayer insulating film 4 may be a silicon oxide film formed by plasma CVD (Chemical Vapor Deposition) in which TEOS (tetraethoxysilane) is used as a raw material. Alternatively, a silicon oxide film (SiOF) containing fluorine (F), a silicon oxide film (SiCN) containing carbon nitride (CN), or any other suitable film can be used. SiOF and SiCN are known as low-dielectric constant materials.

In step 3, a through hole is formed. As shown in FIG. 2, lithography and dry etching are used to form through hole 5 that passes through interlayer insulating film 4 in the thickness direction thereof so that the surface of Al wiring 3 is exposed. The diameter of through hole 5 ranges from 250 to 500 nm.

After through hole 5 is formed, the material (not illustrated in FIG. 2) of a mask used in the dry etching is removed. The series of processes in step 2 are carried out by using a plasma CVD apparatus, a lithography apparatus, and a dry etching apparatus, each of which is a separate apparatus.

In step 4, the semiconductor substrate is loaded into a degassing chamber, one of the multiple chambers of a multi-chamber processing apparatus through which a workpiece can be transported in a vacuum atmosphere. Degassing process is carried out in the degassing chamber. Interlayer insulating film 4 contains unstable impurities, such as water (H₂O) and CO. When the impurities desorb in a later step, formed metal is oxidized, which may prevent Al from reflowing. To allow Al to reflow, degassing process is carried out before the metal formation.

In the degassing process, semiconductor substrate 1 is transferred into the multi-chamber processing apparatus, the inside of which is maintained under vacuum, and heat-treated in a non-oxidative atmosphere at a temperature within a range from 400 to 450° C. for 35 seconds. At the end of the degassing process, the impurities that have desorbed from interlayer insulating film 4 cause Al oxide to be formed on the surface of Al wiring 3 exposed to through hole 5.

Since steps 4 to 13 can be carried out in the multi-chamber apparatus, semiconductor substrate 1 will not be exposed to the outside air during these steps. Metals formed in the steps described above are therefore prevented from being oxidized by the outside air.

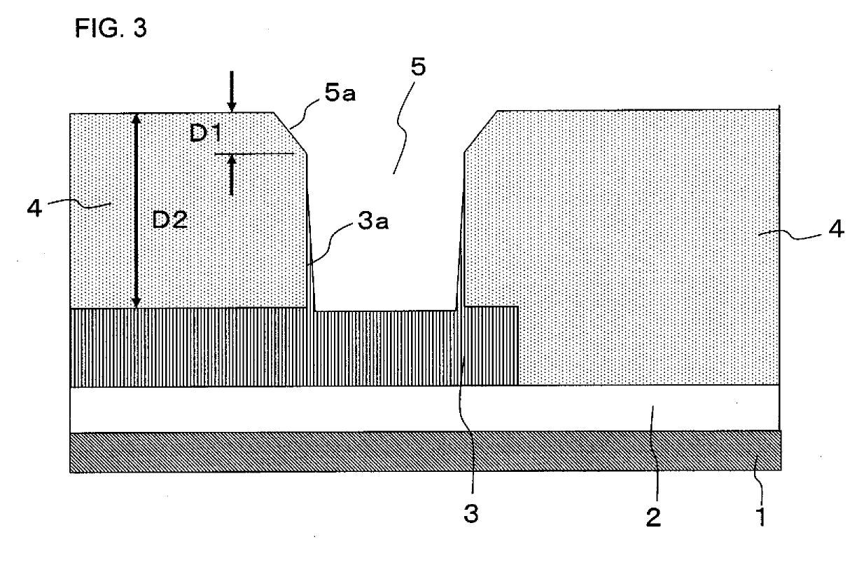

In step 5, the semiconductor substrate is transferred into a sputter-etching chamber of the multiple chambers, and sputter-etching is carried out, as shown in FIG. 3. In step 5, the Al oxide formed in step 4 is removed, otherwise the Al oxide causes conduction failure. In step 5, semiconductor substrate 1 is transferred into the etching chamber, and argon (Ar) gas excited at a high-frequency power ranging from 400 to 600 W, preferably 500 W, is used to sputter-etch entire semiconductor substrate 1. As a result, the Al oxide formed on the surface of Al wiring 3 is sputter-etched away, and resputtered Al oxide 3a is formed on the sidewall of through hole 5. Inclined portion 5a is also formed at the opening of through hole 5.

In the present exemplary embodiment, the sputter-etching period is adjusted in such a way that the depth D1 indicating the intersection of inclined portion 5a and through hole 5 ranges from 15 to 25% of the thickness D2 of interlayer insulating film 4 left on Al wiring 3. Specifically, the sputter-etching is carried out for a period ranging from 30 to 60 seconds. In this process, the diameter of the opening of through hole 5 is enlarged by 2×D1 as compared with that before the sputter-etching is carried out. In the present exemplary embodiment, the nature of sputter-etching, that is, the angle of inclined portion 5a being approximately 45 degrees, is used to enlarge the diameter of the opening of through hole 5. Enlarging the diameter of the opening also advantageously allows an Al reflow process in a later step to be carried out in a reliable manner. In the present specification, the “opening” represents the top portion of the through hole that is farthest from the metal wiring formed on the semiconductor substrate.

In step 6, the semiconductor substrate is transferred into a titanium/titanium nitride formation chamber of the multiple chambers, and a cooling process is carried out. At the time when the sputter-etching process is completed in step 5, the influence of the heat treatment in the degassing process of step 4 remains, and the semiconductor substrate itself is still non-uniformly heated. This condition may adversely affect the formation of titanium/titanium nitride. That is, the film thickness of the titanium/titanium nitride tends to be non-uniform across the semiconductor substrate and the roughness of the surface increases in size. In the present exemplary embodiment, a cooling mechanism is provided in a stage of the titanium/titanium nitride formation apparatus. In cooling step 6, the temperature of the semiconductor substrate is controlled to fall within a range from 20 to 40° C. In the present exemplary embodiment, the temperature of the semiconductor substrate is set to 25° C.

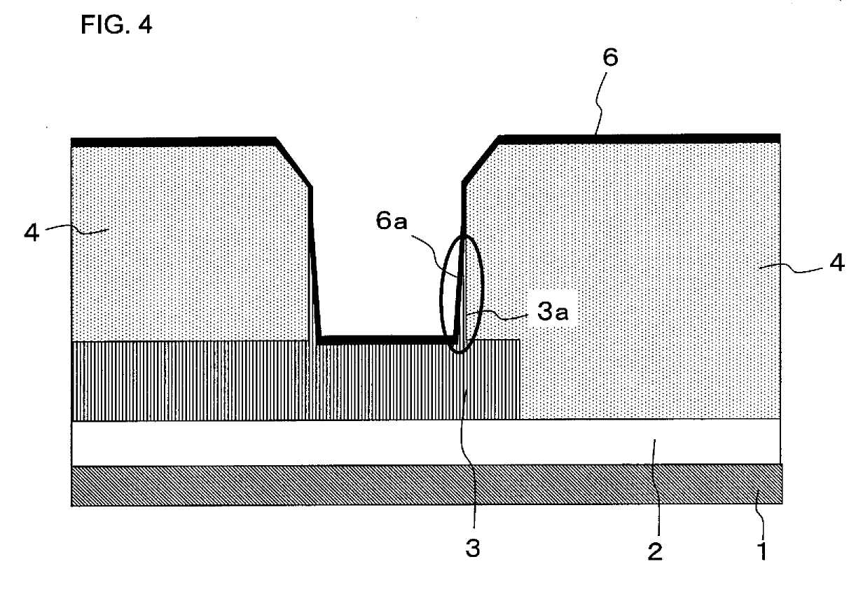

In step 7, first titanium film 6 is formed in the same chamber, as shown in FIG. 4. Specifically, sputtering using Ar excited at a DC power within a range from 35 to 40 kW, preferably 37 kW, is used to form first titanium film 6 in such a way that the film thickness over interlayer insulating film 4 ranges from 18 to 22 nm, preferably 20 nm.

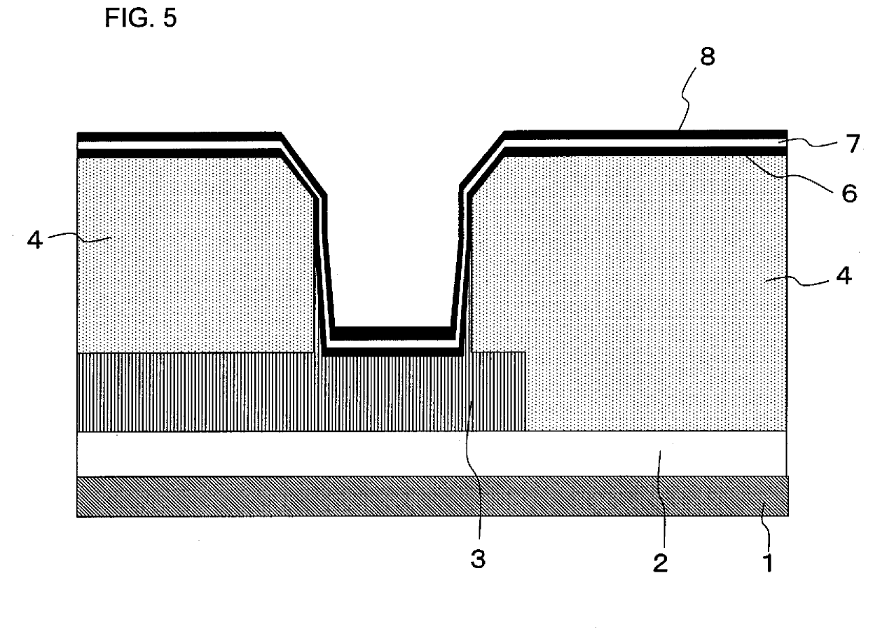

In step 8, titanium nitride film 7 is formed on first titanium film 6, as shown in FIG. 5. Specifically, reactive sputtering using Ar and N₂ excited at a DC power within a range from 30 to 35 kW, preferably 33 kW, is used to form titanium nitride film 7 in such a way that the film thickness over the interlayer insulating film ranges from 18 to 22 nm, preferably 20 nm. Titanium nitride film 7 functions as barrier metal.

Further, in step 9, second titanium film 8 is formed on titanium nitride film 7. Specifically, sputtering using Ar excited at a DC power within a range from 35 to 40 kW, preferably 37 kW, is used to form second titanium film 8 in such a way that the film thickness over the interlayer insulating film ranges from 18 to 22 nm, preferably 20 nm. Providing second titanium film 8 allows junction of the resultant structure with first Al layer 9a, which will be formed in a later step, to improve.

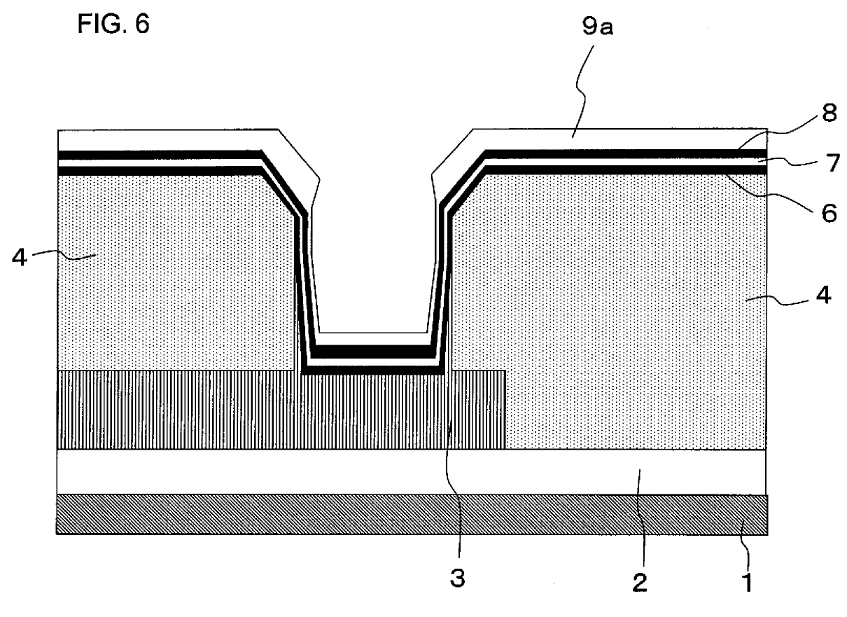

In step 10, the semiconductor substrate is transferred into a chamber for forming the first Al layer and first Al layer 9a is formed, as shown in FIG. 6. Specifically, sputtering using Ar excited at a DC power within a range from 30 to 40 kW, preferably 35 kW, is used to form first Al layer 9a in such a way that the film thickness over interlayer insulating film 4 ranges from 140 to 160 nm, preferably 150 nm. In step 10, a cooling mechanism provided in the chamber for forming the first Al layer maintains the semiconductor substrate, following steps 6 to 9, at a temperature within a range from 20 to 40° C.

In step 11, the semiconductor substrate is transferred into a chamber for forming a second Al layer, and a heating mechanism is used to preheat the semiconductor substrate before the second Al layer is formed. In the preheating process, the stage on which the semiconductor substrate is placed is set at a temperature within a range from 400 to 450° C., preferably 415° C., and the preheating is carried out for 60 seconds to stabilize the temperature of the semiconductor substrate.

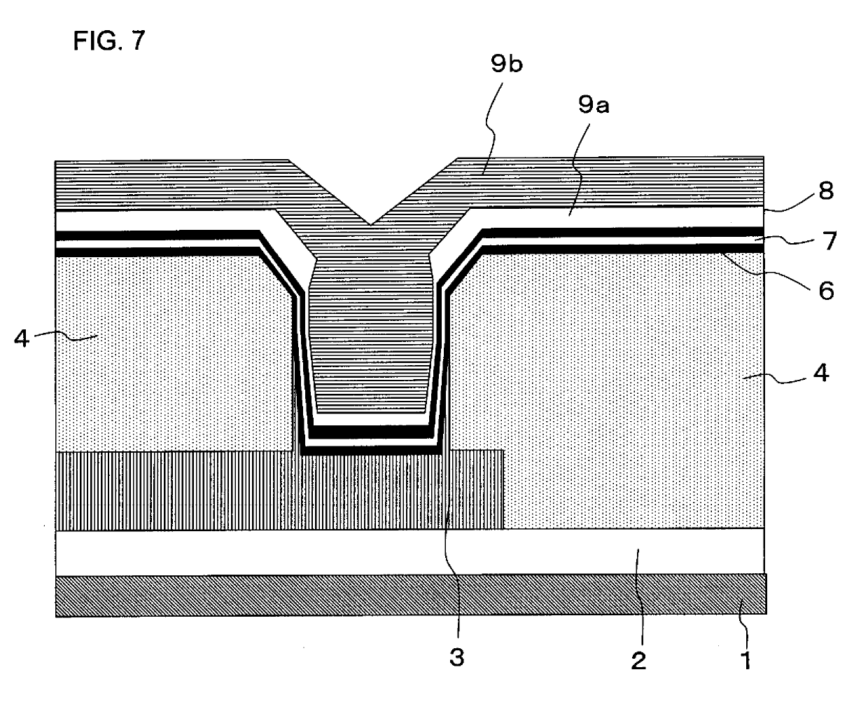

In step 12, a reflow Al layer is formed. In step 12, after the temperature of the semiconductor substrate is stabilized at 415° C., second Al layer 9b is formed, as shown in FIG. 7. Specifically, sputtering using Ar excited at a DC power within a range from 3 to 4 kW, preferably 3.5 kW, is used to form second Al layer 9b in such a way that the film thickness over interlayer insulating film 4 ranges from 250 to 350 nm, preferably 300 nm.

In step 12, the sputter deposition rate is controlled to be a value within a range from 100 to 200 nm/min by reducing the DC power to a value within a range from 3 to 4 kW. Since the reflow process for forming the second Al layer is carried out at a reduced sputter deposition rate, no void is produced in through hole 5 but through hole 5 can be reliably filled with second Al layer 9b. Step 12 is performed until through hole 5 is completely filled with second Al layer 9b. In the present exemplary embodiment, step 12 is completed when the second Al layer 9b is formed over interlayer insulating film 4 to a thickness of 300 nm.

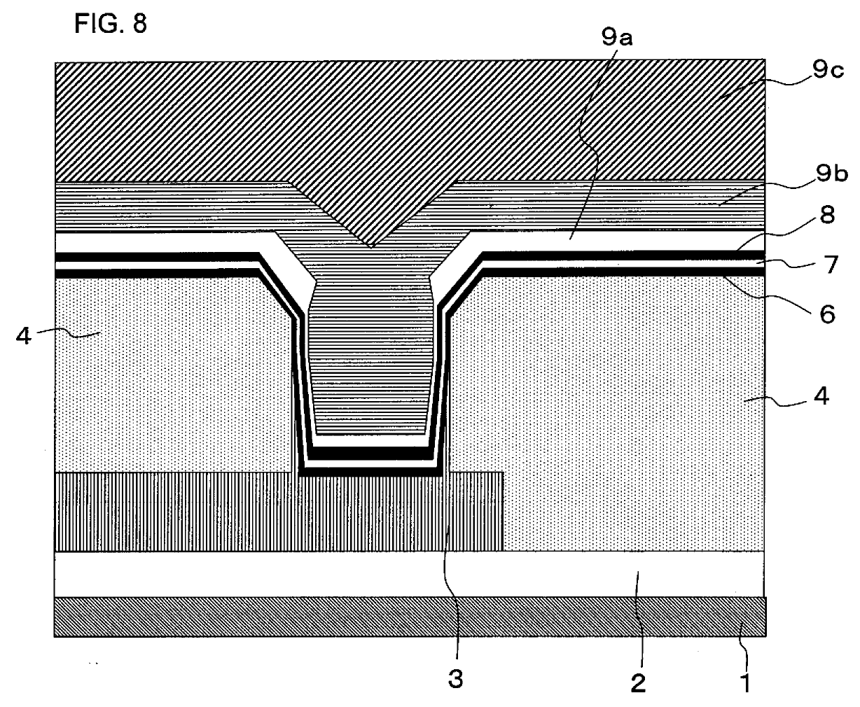

In step 13, third Al layer 9c is formed in the same chamber at the same substrate temperature, as shown in FIG. 8. Specifically, sputtering using Ar excited at a DC power within a range from 20 to 25 kW, preferably 22 kW, is used to form third Al layer 9c in such a way that the film thickness over interlayer insulating film 4 ranges from 500 to 600 nm, preferably 550 nm.

In the present exemplary embodiment, since the through hole has been filled with second Al layer 9b at the end of step 12, it is not necessary in step 13 to prevent voids from being produced. Therefore, the DC power can be greater than that in the formation of the second Al layer to increase the sputtered volume rate. The sputter deposition rate in step 13 is 1000 nm/min or higher.

Although not shown in FIG. 8, after step 13, sputtering is used to form cap titanium nitride on third Al layer 9c to a thickness of approximately 50 nm. Lithography and dry etching are then used to sequentially etch the cap titanium nitride, third Al layer 9c, second Al layer 9b, first Al layer 9a, second titanium film 8, titanium nitride film 7, and first titanium film 6 to form an Al wiring.

In the present exemplary embodiment, when the sputter-etching is carried out to remove the oxide in the surface area of underlying Al wiring 3 and enlarge the diameter of the opening of the through hole in step 5, resputtered Al oxide 3a is formed on the sidewall of through hole 5, as shown in FIG. 3. When first titanium film 6, titanium nitride film 7, and second titanium film 8 are formed on the substrate heated to a temperature within a range from 100 to 200° C. as in related art under the condition that resputtered Al oxide 3a is present, first titanium film 6 in particular is strongly affected by the oxygen in resputtered Al oxide 3a and oxidized, resulting in poor crystallizability of first titanium film 6. As a result, the crystallizability of titanium nitride film 7 and second titanium film 8 formed on first titanium film 6 is also degraded. In this case, Al does not reflow well and hence voids are likely produced. Further, when the first Al layer is formed in a heated condition, the Al grain size disadvantageously increases, which prevents the following second and third Al layer from reflowing. Moreover, when a reflow Al single layer is formed at a relatively fast deposition rate, voids tend to be produced.

In contrast, in the present exemplary embodiment, first titanium film 6, titanium nitride film 7, second titanium film 8, and the first Al layer are formed at a substrate temperature within a range from 20 to 40° C. with resputtered Al oxide 3a formed on the sidewall of through hole 5. Thereafter, the temperature of the substrate is controlled to be 415° C., and the second Al layer is formed in a reflow process at a slow deposition rate to the extent that the through hole is filled, followed by the formation of the third Al layer in a reflow process at a fast deposition rate. Therefore, a low-resistance Al wiring layer can be formed without reduction in productivity, without voids produced in the plug portion in the through hole, but with excellent crystallizability in the wiring over the interlayer insulating film.

### Second Exemplary Embodiment

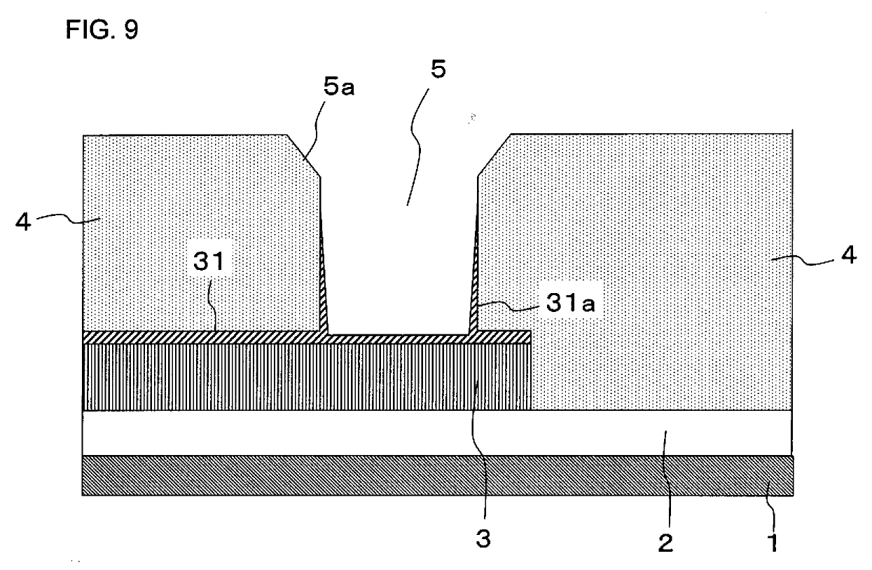

A second exemplary embodiment will be described with reference to FIG. 9. The items other than those described below are the same as those in the first exemplary embodiment, and no description of these items will be made. In the present exemplary embodiment, metal wiring 3 made of Al is formed on semiconductor substrate 1 with interlayer insulating film 2 therebetween, and then titanium nitride film 31 is formed as a barrier film. The barrier titanium nitride film is formed by sputtering to a thickness of approximately 50 nm.

Thereafter, interlayer insulating film 4 is deposited and lithography and dry etching are used to form through hole 5 in the interlayer insulating film 4, as in the first exemplary embodiment. The material of a mask used in the dry etching is removed, and sputter-etching using Ar gas is carried out. The sputter-etching forms inclined portion 5a at the opening of the through hole and enlarges the diameter of the opening, which facilitates an Al reflow process, which will be carried out later. Further, the sputter-etching causes the titanium oxide in the surface area of barrier titanium nitride 31 exposed at the bottom of through hole 5 to undergo sputtering, and resputtered titanium oxide 31a is formed on the side surface of through hole 5.

Experimental results provided by the inventor have shown that resputtered titanium oxide 31a does not degrade the crystallizability of the first titanium film formed thereon, unlike resputtered Al oxide 3a described in the first exemplary embodiment. The reason for this is conceivably that resputtered titanium oxide 31a and the first titanium film are made of the same elemental titanium. Therefore, by coating the surface of metal wiring 3 with the barrier titanium nitride film and forming the titanium-containing resputtered film on the side surface of the through hole, the Al reflow process can be carried out more reliably than in the case where the resputtered Al oxide is formed.

### Comparative Example 1

As Comparative Example 1, a sample was produced according to steps 1 to 11 and 13 of the first exemplary embodiment except step 12 of forming the second Al layer shown in FIG. 1.

### Comparative Example 2

As Comparative Example 2, a sample similar to that in the first exemplary embodiment was produced except that the formation of the first titanium film in step 7, the formation of the titanium nitride film in step 8, and the formation of the second titanium film in step 9 shown in FIG. 1 were carried out at 200° C.

### Evaluation

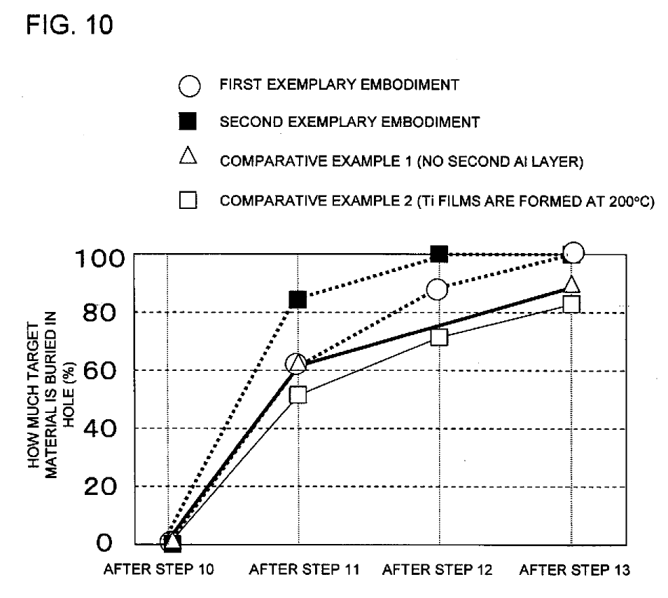

The samples produced in the first exemplary embodiment, the second exemplary embodiment, Comparative Example 1, and Comparative Example 2 were evaluated in terms of how much Al is buried in the through hole by observing cross sections of the samples under a scanning electron microscope. Twenty through holes were observed per sample, and FIG. 10 shows how much Al is buried on average.

It is found that in all the samples in the first exemplary embodiment, the through hole is completely filled with Al at the end of final step 13. It is found that in all the samples in the second exemplary embodiment, the through hole is completely filled with Al at the end of step 12.

It is, however, found that in the samples in Comparative Examples 1 and 2, voids are produced even at the end of final step 13 and the through hole is not completely filled with Al.

It is apparent that the present invention is not limited to the above embodiments, but may be modified and changed without departing from the scope and spirit of the invention.

What is claimed is:

1. A method for manufacturing a semiconductor device, the method comprising:
forming a metal wiring on a semiconductor substrate;
forming an insulating film over the semiconductor substrate with the metal wiring;
forming a through hole passing through the insulating film in a thickness direction thereof so that an upper surface of the metal wiring is exposed;
performing sputter-etching to enlarge a cross-sectional area of an opening of the through hole;
forming a first titanium film, a titanium nitride film, and a second titanium film in this order over the insulating film including an inner surface of the through hole at a temperature within a range from 20 to 40° C.;
forming a first Al layer on the second titanium film;
forming a second Al layer on the first Al layer; and
forming a third Al layer on the second Al layer.

2. A method for manufacturing a semiconductor device, the method comprising:
forming a metal wiring on a semiconductor substrate;
forming an insulating film over the semiconductor substrate with the metal wiring;
forming a through hole passing through the insulating film in a thickness direction thereof so that an upper surface of the metal wiring is exposed;
performing sputter-etching to enlarge a cross-sectional area of an opening of the through hole;
forming a first conductive film, a second conductive film, and a third conductive film in this order over the insulating film including an inner surface of the through hole at a temperature within a range from 20 to 40° C.;
forming a fourth conductive film on the third conductive film;
forming a fifth conductive film on the fourth conductive film; and
forming a sixth conductive film on the fifth conductive film.

3. The method for manufacturing a semiconductor device according to claim 2,
wherein the first conductive film is a first titanium film,
the second conductive film is a titanium nitride film,
the third conductive film is a second titanium film,
the fourth conductive film is a first Al layer,
the fifth conductive film is a second Al layer, and
the sixth conductive film is a third Al layer.

4. The method for manufacturing a semiconductor device according to claim 3,
further comprising performing degassing, after forming the through hole before performing the sputter-etching.

5. The method for manufacturing a semiconductor device according to claim 4,
wherein in performing degassing, the semiconductor substrate is heat-treated at a temperature within a range from 400 to 450° C.

6. The method for manufacturing a semiconductor device according to claim 4,
further comprising cooling the semiconductor substrate, after performing the sputter-etching following performing degassing before forming the first titanium film.

7. The method for manufacturing a semiconductor device according to claim 6,
wherein in cooling the semiconductor substrate, the semiconductor substrate is cooled to a temperature within a range from 20 to 40° C.

8. The method for manufacturing a semiconductor device according to claim 6,
further comprising forming a wiring protective layer on the metal wiring, after cooling the semiconductor substrate before forming the first titanium film.

9. The method for manufacturing a semiconductor device according to claim 3,
wherein steps from performing the sputter-etching to forming the third Al layer are carried out continuously in such a way that the semiconductor substrate is not exposed to an outside air.

10. The method for manufacturing a semiconductor device according to claim 3,
wherein the first Al layer is formed under condition of a temperature within a range from 20 to 40° C. and the atmosphere having a pressure within a range from 0.1 to 0.5 mTorr.

11. The method for manufacturing a semiconductor device according to claim 3,
wherein the second Al layer and the third Al layer are formed at a temperature within a range from 400 to 450° C.

12. The method for manufacturing a semiconductor device according to claim 3,
further comprising preheating the semiconductor substrate after forming the first Al layer before forming the second Al layer.

13. The method for manufacturing a semiconductor device according to claim 3,
wherein a rate for forming the second Al layer is slower than a rate for forming the third Al layer.

14. The method for manufacturing a semiconductor device according to claim 3,
further comprising sequentially etching the third Al layer, the second Al layer, the first Al layer, the second titanium film, the titanium nitride film, and the first titanium film to form an Al wiring, after forming the third Al layer.

15. The method for manufacturing a semiconductor device according to claim 3,
further comprising forming a cap titanium nitride film on the third Al layer, after forming the third Al layer.

16. The method for manufacturing a semiconductor device according to claim 2,
wherein the metal wiring is an Al wiring.

17. The method for manufacturing a semiconductor device according to claim 2,
wherein the metal wiring is a Cu wiring.
